(19) United States
(12) Patent Application Publication
(10) Pub. No.: US 2018/0007790 A1
(43) Pub. Date: Jan. 4, 2018

(54) CIRCUIT BOARD MODULE AND CHIP MODULE

(71) Applicant: Unlimiter MFA Co., Ltd., Eden Island (SC)

(72) Inventors: Kuo-Ping YANG, Taipei (TW); Neo Bob Chih-Yung YOUNG, Taipei (TW); Lin-He CHU, Taipei (TW); Wen-Chiang WU, Taipei (TW); Shih-Kang HUANG, Taipei (TW); Yi-Yen CHIANG, Taipei (TW)

(21) Appl. No.: 15/359,999

(22) Filed: Nov. 23, 2016

(30) Foreign Application Priority Data
Jul. 1, 2016 (TW) 105120941

(51) Int. Cl. H05K 1/18; H01L 23/498

(52) U.S. Cl. CPC H05K 1/18; H01L 23/49827; H05K 2201/10378

(57) ABSTRACT

A circuit board module is disclosed. The circuit board module includes a circuit board and an adaption board. The adaption board is placed on the circuit board such that a chip can be placed thereon. The chip is electrically connected to the circuit board by the adaption board.

### BACKGROUND OF THE INVENTION

### 1. Field of the Invention

The present invention relates to a circuit board module; more particularly, the present invention relates to a circuit board module provided with a microchip.

### 2. Description of the Related Art

Due to the trend of electronic product miniaturization, more and more electronic products have smaller and smaller interior spaces for placing electronic components. However, to meet the need to continuously improve product functions, it is also necessary to install many processing chips. Therefore, it is an important task to increase the number of processing chips or other electronic components installed within a limited space.

Therefore, there is a need to provide a circuit board module and a chip module to mitigate and/or obviate the aforementioned problems.

### SUMMARY OF THE INVENTION

It is an object of the present invention to provide a circuit board module which can be combined with a chip, wherein the chip has a plurality of pins. The circuit board module comprises a circuit board and an adaption board. The adaption board is placed on the circuit board. The adaption board has a top surface whereon the chip can be placed. The top surface is provided with a plurality of contacts electrically connected to the circuit board. The plurality of contacts can contact the plurality of pins of the chip such that the chip is electrically connected to the circuit board by the adaption board.

According to one embodiment of the present invention, the adaption board comprises at least one accommodating groove which allows at least one electronic component to be placed therein such that the at least one electronic component is electrically connected to the circuit board directly.

According to one embodiment of the present invention, the adaption board further comprises a bottom surface and a plurality of conductive pillars. Each of the conductive pillars has a head end and a tail end. The head ends are located on the top surface of the adaption board, and the tail ends are located on the bottom surface of the adaption board. The head ends of the plurality of conductive pillars are the plurality of contacts, and the tail ends of the plurality of conductive pillars are electrically connected to the circuit board.

According to one embodiment of the present invention, the chip directly covers the adaption board such that the at least one electronic component is covered by the chip.

According to one embodiment of the present invention, the adaption board covers the circuit board.

It is another object of the present invention to provide a chip module which comprises a chip and a circuit board module. The chip has a plurality of pins. The circuit board module includes a circuit board and an adaption board. The adaption board is placed on the circuit board. The adaption board has a top surface which allows the chip to be placed thereon. The top surface is provided with a plurality of contacts electrically connected to the circuit board. The plurality of contacts directly contact the plurality of pins such that the chip is electrically connected to the circuit board by the adaption board.

According to one embodiment of the present invention, the adaption board comprises at least one accommodating groove which allows at least one electronic component to be placed therein such that the at least one electronic component is electrically connected to the circuit board directly.

According to one embodiment of the present invention, the adaption board further comprises a bottom surface and a plurality of conductive pillars. Each of the conductive pillars has a head end and a tail end. The head end of each of the plurality of conductive pillars is located on the top surface of the adaption board, and the tail end of each of the plurality of conductive pillars is located on the bottom surface of the adaption board. The head ends of the plurality of conductive pillars are the plurality of contacts, and the tail ends of the plurality of conductive pillars are electrically connected to the circuit board.

According to one embodiment of the present invention, the chip directly covers the adaption board such that the at least one electronic component is covered by the chip.

According to one embodiment of the present invention, the adaption board directly covers the circuit board.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only and not as a definition of the invention.

In the drawings, wherein similar reference numerals denote similar elements throughout the several views:

FIG. 1 illustrates a top view of a chip module according to the present invention.

FIG. 2 illustrates a bottom view of the chip module according to the present invention.

FIG. 3 illustrates a cross sectional view of section A-A as shown in FIG. 1 according to the present invention.

### DETAILED DESCRIPTION OF THE PREFERRED EMBODIMENT

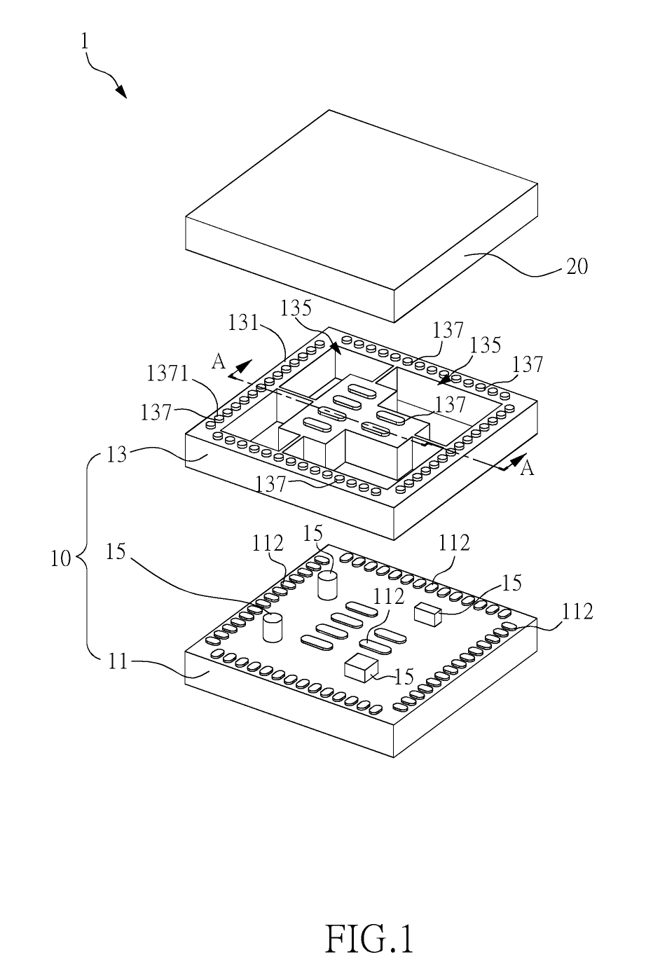

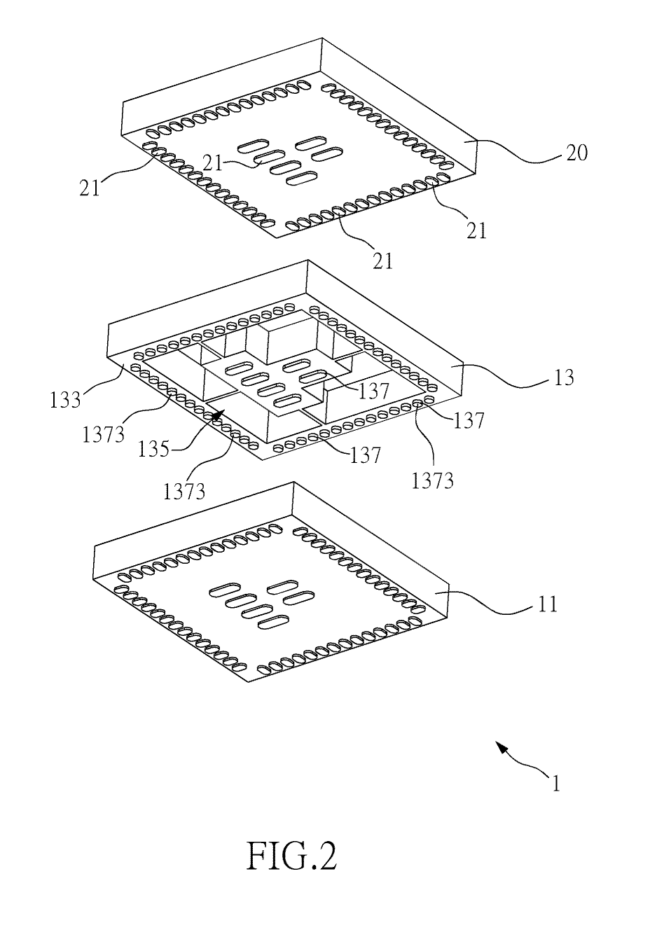

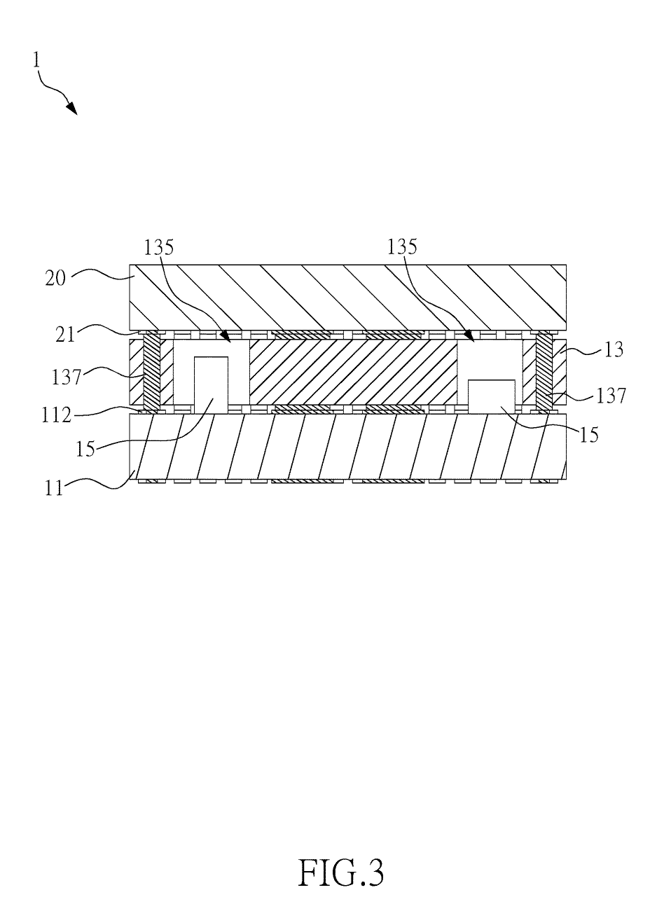

Please refer to FIG. 1 to FIG. 3. FIG. 1 illustrates a top view of a chip module according to the present invention; FIG. 2 illustrates a bottom view of the chip module according to the present invention; FIG. 3 illustrates a cross sectional view of section A-A as shown in FIG. 1 according to the present invention.

As shown in FIG. 1 and FIG. 2, in one embodiment of the present invention, the chip module 1 of the present invention comprises a circuit board module 10 and a chip 20.

In one embodiment of the present invention, the circuit board module 10 comprises a circuit board 11, an adaption board 13 and a plurality of electronic components 15. The circuit board 11 is provided with pin areas 112.

In one embodiment of the present invention, the adaption board 13 has a top surface 131 and a bottom surface 133 corresponding to each other, and the adaption board 13 includes a plurality of accommodating grooves 135 and a plurality of conductive pillars 137. Each conductive pillar 137 has a head end 1371 and a tail end 1373. The head end 1371 of the conductive pillar 137 is located at the top surface 131 of the adaption board 13. The tail end 1373 of the conductive pillar 137 is located at the bottom surface 133 of the adaption board 13. That is, each of the conductive pillars 137 penetrates the adaption board 13.

The adaption board 13 is superposed on the circuit board 11, and the surface area of the adaption board 13 is substantially equal to the surface area of the circuit board 11 so as to cover directly the circuit board 11. Each of the tail ends 1373 of the plurality of conductive pillars 137 is respectively and electrically connected to each of the pin areas 112 on the circuit board 11. As a result, the adaption board 13 can be electrically connected to the circuit board 11.

The plurality of electronic components 15, such as capacitors, inductors, resistors or circuits, are provided on the circuit board 11, and the electronic components 15 are placed in each of the accommodating grooves 135 (as shown in FIG. 3).

In one embodiment of the present invention, the chip 20, such as a microprocessor chip, includes a plurality of pins 21. The chip 20 is superposed on the top surface 131 of the adaption board 13, and the surface area of the chip 20 is substantially equal to the surface area of the adaption board 13 so as to cover directly the adaption board 13. Each of the plurality of pins 21 of the chip 20 is respectively contacted with the head end 1371 of each of the conductive pillars 137 of the adaption board 13 such that the chip 20 is electrically connected to the circuit board 11 by the conductive pillars 137 of the adaption board 13.

According to the above description, by means of providing the adaption board 13 as disclosed in the present invention, a chip 20 with a comparatively larger surface area can be placed thereon, and the chip 20 can be electrically connected to the circuit board 11 by the conductive pillars 137. Therefore, the required surface area of the circuit board 11 can be reduced.

Although the present invention has been explained in relation to its preferred embodiments, it is to be understood that many other possible modifications and variations can be made without departing from the spirit and scope of the invention as hereinafter claimed.

What is claimed is:

1. A circuit board module, combined with a chip, the chip comprising a plurality of pins, the circuit board modules comprising;
a circuit board; and
an adaption board, superposed on the circuit board, the adaption board having a top surface allowing the chip to be superposed thereon, wherein the top surface comprises a plurality of contacts electrically connected to the circuit board, and the plurality of contacts directly contact the plurality of pins such that the chip is electrically connected to the circuit board by the adaption board.

2. The circuit board module as claimed in claim 1, wherein the adaption board comprises at least one accommodating groove allowing at least one electronic component to be placed therein such that the at least one electronic component is electrically connected to the circuit board directly.

3. The circuit board module as claimed in claim 1, wherein the adaption board further comprises a bottom surface and a plurality of conductive pillars, and each of the conductive pillars has a head end and a tail end; each head end is located on the top surface, and each tail end is located on the bottom surface; the head ends of the plurality of conductive pillars are the plurality of contacts, and the tail ends of the plurality of conductive pillars are electrically connected to the circuit board.

4. The circuit board module as claimed in claim 3, wherein the chip directly covers the adaption board such that the at least one electronic component is covered by the chip.

5. The circuit board module as claimed in claim 4, wherein the adaption board directly covers the circuit board.

6. A chip module, comprising:
a chip, comprising a plurality of pins; and
a circuit board module, comprising:
a circuit board; and
an adaption board, superposed on the circuit board, the adaption board having a top surface allowing the chip to be superposed thereon, wherein the top surface comprises a plurality of contacts electrically connected to the circuit board, and the plurality of contacts directly contact the plurality of pins such that the chip is electrically connected to the circuit board by the adaption board.

7. The chip module as claimed in claim 6, wherein the adaption board comprises at least one accommodating groove allowing at least one electronic component to be placed therein such that the at least one electronic component is electrically connected to the circuit board directly.

8. The chip module as claimed in claim 6, wherein the adaption board further comprises a bottom surface and a plurality of conductive pillars, each of the conductive pillars having a head end and a tail end; each head end is located on the top surface, and each tail end is located on the bottom surface; the head ends of the plurality of conductive pillars are the plurality of contacts, and the tail ends of the plurality of conductive pillars are electrically connected to the circuit board.

9. The chip module as claimed in claim 8, wherein the chip directly covers the adaption board such that the at least one electronic component is covered by the chip.

10. The chip module as claimed in claim 9, wherein the adaption board directly covers the circuit board.
